(19) United States
(12) Patent Application Publication
(10) Pub. No.: US 2025/0151563 A1
(43) Pub. Date: May 8, 2025

(54) DISPLAY DEVICE

(71) Applicant: LG Display Co., Ltd., Seoul (KR)

(72) Inventors: Jaehwan MYUNG, Paju-si (KR); Minki KIM, Paju-si (KR)

(21) Appl. No.: 18/889,231

(22) Filed: Sep. 18, 2024

(30) Foreign Application Priority Data
Nov. 8, 2023 (KR) 10-2023-0153443

(51) Int. Cl. H10K 59/35; H10K 59/124; H10K 102/00

(52) U.S. Cl. CPC H10K 59/353; H10K 59/124; H10K 59/352; H10K 2102/3026

(57) ABSTRACT

The present specification relates to a display device in which an ultra-high resolution can be implemented at half the prices of conventional display devices. To achieve the same, in the display device of the present specification, small-sized and ultra-high resolution pixels may be disposed in a central area of a display panel, and pixels greater and cheaper than the pixels disposed in the central area may be disposed in a peripheral active area surrounding the central area.

### CROSS-REFERENCE TO RELATED APPLICATION

The present application claims priority to Korean Patent Application No. 10-2023-0153443, filed Nov. 8, 2023, the entire contents of which is incorporated herein for all purposes by this reference.

### BACKGROUND

### Technical Field

The present specification relates to a display device, and more specifically, to a display device in which an ultra-high resolution is implemented.

### Description of the Related Art

Display devices include an active area in which images are displayed and a non-active area formed along an outer edge portion of the active area. In addition to the display panel for displaying the images, the display device requires various additional components such as a driving integrated circuit or a circuit board.

The non-active area includes a bezel area, and the bezel area is bent at 180 degrees and permanently maintains a folded state.

In application of augmented reality (AR), the display device may be small and have a high resolution of 3000 PPI or more.

### BRIEF SUMMARY

Display devices use an organic light emitting diode on silicon (hereinafter referred to as “OLEDOS”) to realize augmented reality (AR), but the prices of products are 10 times or more the prices of conventional products.

Therefore, virtual reality (VR) is being implemented by using inexpensive organic light emitting diodes on glass (hereinafter referred to as “OLEDOG”).

However, the OLEDoG type display devices have a problem in that it is difficult to manufacture display panels of 1400 PPI or higher.

The inventors of the present specification invented a display device in which an ultra-high resolution can be implemented with reduced costs.

Embodiments of the present specification are directed to providing a display device in which small-sized and ultra-high resolution pixels are disposed in a central area of a display panel and pixels greater and cheaper than the pixels disposed in the central area are disposed in a peripheral active area surrounding the central area.

The technical characteristics and features of the present specification are not limited to those described above, and other technical characteristics and features of the present specification which are not mentioned herein can be understood by the following description and more clearly understood by embodiments of the present specification. In addition, it will be able to be easily seen that the technical features and characteristics of the present specification can be achieved by devices and combinations thereof that are described in the claims.

There may be provided a display device according to one embodiment of the present specification. In the display device, one or more first sub-pixels may be disposed in a first active area, one or more second sub-pixels may be disposed in a second active area surrounding the first active area, and one or more third sub-pixels may be disposed in a third active area surrounding the second active area.

In addition, the first active area may have a higher resolution than the second active area and the third active area.

In addition, an area of the third sub-pixel may have a greater area than an area of the first sub-pixel or an area of the second sub-pixel.

### BRIEF DESCRIPTION OF THE SEVERAL VIEWS OF THE DRAWINGS

FIG. 1 is a view schematically showing a display device according to an embodiment of the present specification.

FIG. 2A is a view showing an example of pixels disposed in each active area of a display panel according to an embodiment of the present specification.

FIG. 2B is a view showing an example of pixels disposed in each active area of a display panel according to a second embodiment of the present specification.

FIG. 2C is a view showing an example of pixels disposed in each active area of a display panel according to a third embodiment of the present specification.

FIG. 3 is a schematic cross-sectional view showing a first display panel according to an embodiment of the present specification.

FIG. 4 is a schematic cross-sectional view showing a second display panel according to the embodiment of the present specification.

FIG. 5 is a schematic cross-sectional view showing a display panel according to the embodiment of the present specification.

FIG. 6A is a cross-sectional view showing a cross-sectional structure of a first display panel 10′ according to the second embodiment of the present specification.

FIG. 6B is a cross-sectional view showing a cross-sectional structure of a first display panel 10 according to the third embodiment of the present specification.

FIG. 7A is a cross-sectional view schematically showing a cross-sectional structure of an opening of the first display panel according to the embodiment of the present specification.

FIG. 7B is a cross-sectional view schematically showing a cross-sectional structure of an opening of a first display panel according to another embodiment of the present specification.

FIG. 8A is a cross-sectional view showing a cross-sectional structure of a second display panel 20′ according to the second embodiment of the present specification.

FIG. 8B is a cross-sectional view showing a cross-sectional structure of a second display panel 20 according to the third embodiment of the present specification.

FIG. 9 is a view showing an example in which a pad portion is connected when a TFT is manufactured on the second display panel according to the embodiment of the present specification.

FIGS. 10A and 10B are views showing an example in which the pad portion is formed on the display panel according to the embodiment of the present specification.

### DETAILED DESCRIPTION

The above-described technical characteristics, features, and improvements will be described below in detail with reference to the accompanying drawings, and thus those skilled in the art to which the present disclosure pertains will be able to easily carry out the technical spirit of the present disclosure. In describing the present disclosure, when it is determined that a detailed description of the known technology related to the present disclosure may unnecessarily obscure the gist of the present disclosure, a detailed description thereof will be omitted. Hereinafter, exemplary embodiments according to the present disclosure will be described in detail with reference to the accompanying drawings. In the drawings, the same reference numerals are used to denote the same or similar components.

In addition, when a first component is described as being “connected,” “coupled,” or “joined” to a second component, the components may be directly connected or joined, but it should be understood that a third component may be “interposed” between the components, or the components may be “connected,” “coupled,” or “joined” through the third component.

Unless otherwise defined, all terms (including technical and scientific terms) used in the specification may be used as meaning commonly understood by those skilled in the art to which the present disclosure pertains. In addition, terms defined in commonly used dictionaries are not construed ideally or excessively unless clearly and specially defined.

Hereinafter, according to embodiments of the present specification, a display device in which small-sized and ultra-high resolution pixels are disposed in a central area of a display panel and pixels greater and cheaper than the pixels disposed in the central area are disposed in a surrounding active area surrounding the central area will be described.

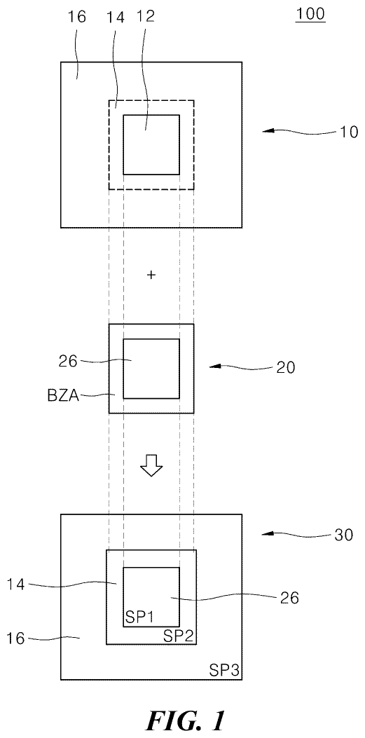

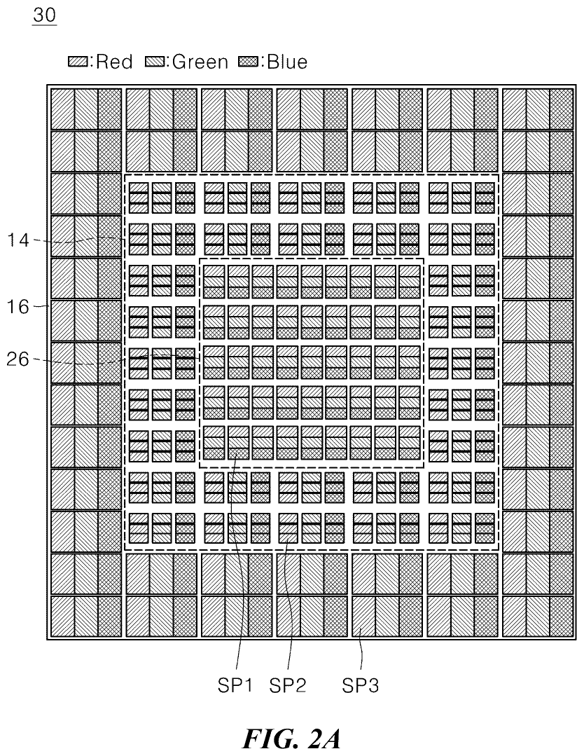

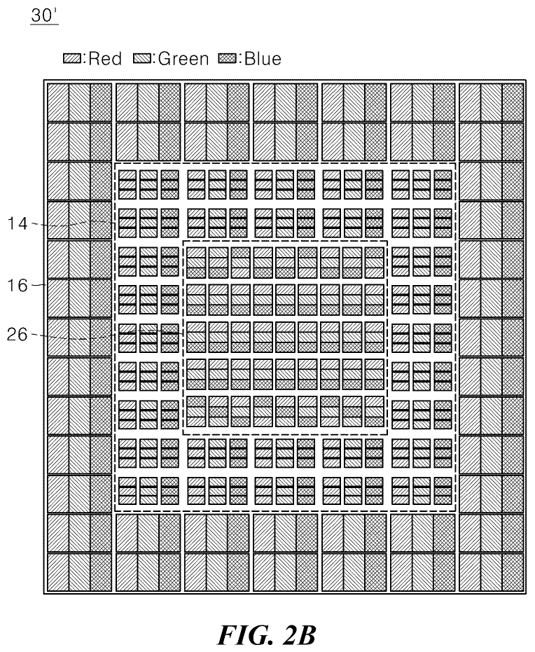

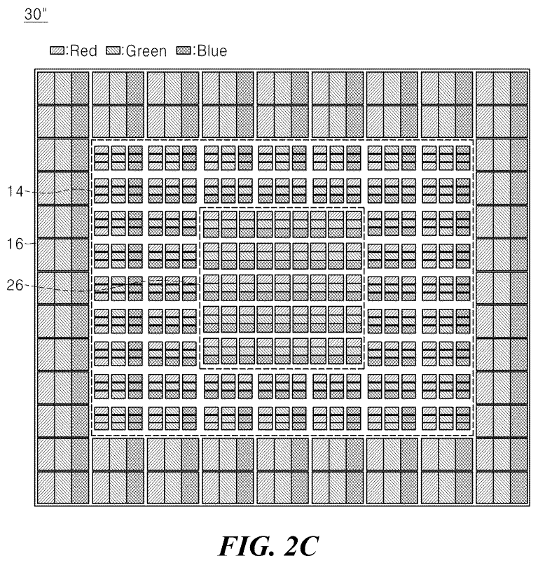

FIG. 1 is a view schematically showing a display device according to an embodiment of the present specification, and FIG. 2A is a view showing an example of pixels disposed in each active area of a display panel according to an embodiment of the present specification.

Referring to FIGS. 1 and 2A, a display device 100 according to an embodiment of the present specification may include a display panel 30 disposed on a front surface thereof.

The display panel 30 may include a first active area 26, a second active area 14, and a third active area 16.

The first active area 26 may include one or more first sub-pixels SP1.

The second active area 14 may include one or more second sub-pixels SP2 and may be disposed in the form of surrounding the first active area 26.

The third active area 16 may include one or more third sub-pixels SP3 and may be disposed in the form of surrounding the second active area 14.

The display panel 30 may include a first display panel 10 and a second display panel 20. The first display panel 10 may be an organic light emitting diode on glass (OLEDoG) type panel, and the second display panel 20 may be an organic light emitting diode on silicon (OLEDoS) type panel.

The first display panel 10 may include an opening 12 corresponding to the first active area 26, the second active area 14 disposed to surround the opening 12, and the third active area 16 disposed to surround the second active area 14.

The second display panel 20 may include the first active area 26 and a bezel area BZA corresponding to the second active area 14 and disposed to surround the first active area 26. The bezel area BZA may be disposed along an outermost edge of the second display panel 20 in the form of surrounding the first active area 26.

In the first display panel 10, an overlapping area that overlaps the bezel area BZA of the second display panel 20 may be the second active area 14.

The first active area 26 may have the same size or area as the opening 12. The first active area 26 may have a greater size or area than the opening 12. The first display panel 10 may be disposed above the second display panel 20. The first display panel 10 may be disposed above the second display panel 20 so that the opening 12 corresponds to the first active area 26. The first display panel 10 may be disposed above the second display panel 20 so that the second active area 14 corresponds to the bezel area BZA. For example, the second display panel 20 fully covers the opening 12.

The first display panel 10 may emit light in a bottom emission method, and the second display panel 20 may emit light in a top emission method in which light from a light emitting element OLED is output in a direction opposite to a substrate.

The first active area 26 may overlap the opening 12, and the second active area 14 may overlap the bezel area BZA.

The second active area 14 may have the same size or area as the bezel area BZA. The second active area 14 may have a greater size or area than the bezel area BZA.

The first active area 26 may have a higher resolution than the second active area 14. The first active area 26 may have a higher resolution than the third active area 16. The first active area 26 may have a higher resolution than the second active area 14 and the third active area 16.

Referring to FIG. 2A, in a display panel 30 according to the first embodiment of the present specification, the first active area 26 may include one or more first sub-pixels SP1.

The one or more first sub-pixels SP1 may include a first sub-pixel SP1 emitting red light, a first sub-pixel SP1 emitting green light, and a first sub-pixel SP1 emitting blue light.

In the display panel 30 according to the first embodiment of the present specification, the second active area 14 may include one or more second sub-pixels SP2.

The one or more second sub-pixels SP2 may include a second sub-pixel SP2 emitting red light, a second sub-pixel SP2 emitting green light, and a second sub-pixel SP2 emitting blue light.

One of the one or more second sub-pixels SP2 disposed in the second active area 14 may have the width of 1 mm to 2 mm.

In the display panel 30 according to the first embodiment of the present specification, the third active area 16 may include one or more third sub-pixels SP3.

The one or more third sub-pixels SP3 may include a third sub-pixel SP3 emitting red light, a third sub-pixel SP3 emitting green light, and a third sub-pixel SP3 emitting blue light.

One third sub-pixel SP3 may have a greater area than one first sub-pixel SP1. One third sub-pixel SP3 may have a greater area than one second sub-pixel SP2. The area of the third sub-pixel SP3 may be greater than the area of the first sub-pixel SP1 and may be greater than the area of the second sub-pixel SP2.

The second display panel 20 may have a greater area than the opening 12 of the first display panel 10.

The first sub-pixel SP1, the second sub-pixel SP2, and the third sub-pixel SP3 may each emit light in one of red (R), green (G), and blue (B).

Referring to FIG. 2A, the first active area 26 may have red (R), green (G), and blue (B) sub-pixels repeatedly disposed in a first direction, e.g., a vertical direction.

In this case, the second active area 14 and the third active area 16 may have red (R), green (G), and blue (B) sub-pixels repeatedly disposed in a second direction, e.g., horizontal direction, which is different from the first direction, e.g., orthogonal to the first direction.

The second active area 14 is an overlapping area that overlaps the bezel area BZA of the second display panel 20 and outputs red (R) light, green (G) light, and blue (B) light through one or more second sub-pixels SP2 on the bezel area BZA.

In the first display panel 10, one second sub-pixel SP2 or one third sub-pixel SP3 may have, for example, the resolution of 1,166 PPI and the size of 21.78 μm.

In the second display panel 20, one first sub-pixel SP1 may have, for example, the resolution of 3,500 PPI and the size of 7.26 μm.

FIG. 2B is a view showing an example of pixels disposed in each active area of a display panel according to a second embodiment of the present specification.

Referring to FIG. 2B, a display panel 30′ according to the second embodiment of the present specification may be disposed so that pixels adjacent to each other among one or more first sub-pixels SP1 disposed in the first active area 26 and one or more second sub-pixels SP2 disposed in the second active area 14 have the same color.

For example, in the first active area 26, one or more first sub-pixels SP1 adjacent to the second active area 14 are disposed so that the one or more first sub-pixels SP1 adjacent to the second active area 14, e.g., in the first direction or vertical direction, have the same color as the adjacent second sub-pixels SP2 in the second active area 14.

In FIG. 2B, in the second active area 14, the upper or lower second sub-pixels SP2 adjacent to the first active area 26 are disposed by repeating R, G, and B colors 3 times.

Therefore, in the first active area 26, one or more first sub-pixels SP1 adjacent to the second active area 14 are disposed by repeating R, G, and B colors three times to have the same color as the adjacent second sub-pixels SP2 of the second active area 14.

In the next lower row at the upper side of the first active area 26, one or more first sub-pixels SP1 are disposed by repeating G, R, and G colors, e.g., by three times, and in the subsequent lower row, disposed by repeating B, B, and R colors, e.g., by three times.

In the next upper row at the lower side of the first active area 26, one or more first sub-pixels SP1 are disposed by repeating G, B, and G colors, e.g., by three times, and in the subsequent upper row, disposed by repeating B, R, and R colors, e.g., by three times.

FIG. 2C is a view showing an example of pixels disposed in each active area of a display panel according to a third embodiment of the present specification.

Referring to FIG. 2C, in the second active area 14, which is the overlapping area, of the display panel 30 according to the third embodiment of the present specification, the second sub-pixels SP2 adjacent to the first active area 26, e.g., in the second direction, may be disposed to have the same color as the first sub-pixels SP1, and the second sub-pixels SP2 adjacent to the third active area 16, e.g., in first direction, may be disposed to have the same color as the third sub-pixels SP3.

For example, in the second active area 14 according to the third embodiment of the present specification, one or more second sub-pixels SP2 adjacent to the third active area 16 may be disposed to have the same color as the adjacent third sub-pixels SP3 in the third active area 16, and one or more second sub-pixels SP2 adjacent to the first active area 26 may be disposed to have the same color as the adjacent first sub-pixels SP1 of the first active area 26.

In FIG. 2C, in the first active area 26, the first sub-pixels SP1 each having R, G, and B colors in the vertical direction are disposed in a row (horizontal) direction.

Therefore, in the second active area 14, the second sub-pixels SP2 each having R, G, and B colors in the vertical direction are disposed in the row (horizontal) direction so that one or more second sub-pixels SP2 adjacent to the first active area 26, e.g., in the row (horizontal) direction, have the same color as the adjacent first sub-pixels SP1 of the first active area 26.

Meanwhile, in the third active area 16, the third sub-pixels SP3 disposed in R, G, and B colors in the horizontal direction are disposed in a column (vertical) direction.

Therefore, in the second active area 14, the second sub-pixels SP2 disposed in R, G, and B colors in the horizontal direction are disposed in the column (vertical) direction so that one or more second sub-pixels SP2 adjacent to the third active area 16, e.g., in the column (vertical) direction, have the same color as the adjacent third sub-pixels SP3 of the third active area 16.

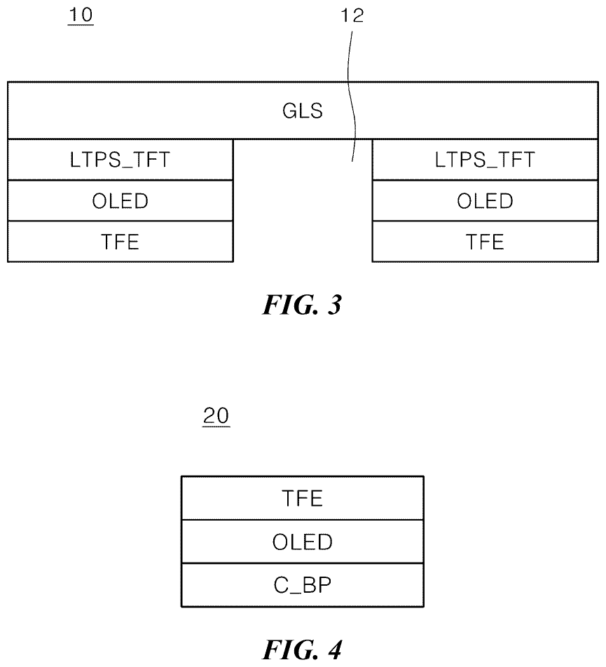

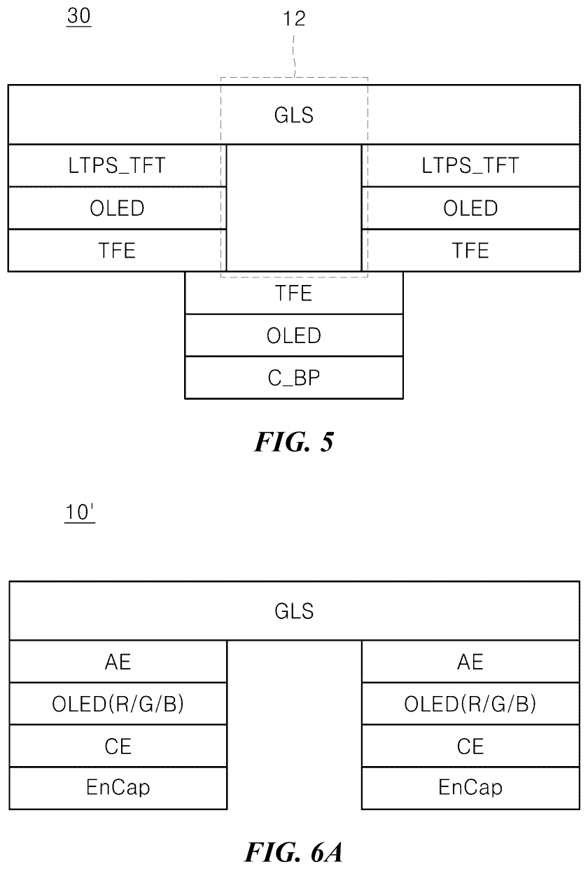

FIG. 3 is a schematic cross-sectional view showing a first display panel according to an embodiment of the present specification, FIG. 4 is a schematic cross-sectional view showing a second display panel according to the embodiment of the present specification, and FIG. 5 is a schematic cross-sectional view showing a display panel according to the embodiment of the present specification.

Referring to FIG. 3, the first display panel 10 according to the embodiment of the present specification may have a thin film insulating layer TFE at one side and a thin film insulating layer TFE at the other side that are disposed with the opening 12 interposed therebetween.

In addition, a light emitting element OLED at one side and a light emitting element OLED at the other side may be disposed on the thin film insulating layer TFE at the one side and the thin film insulating layer TFE at the other side, respectively, with the opening 12 interposed therebetween. Here, the light emitting element OLED may include an anode electrode, a light emitting layer disposed on the anode electrode, and a cathode electrode disposed on the light emitting layer.

In addition, a thin film transistor layer LTPS_TFT at one side and a thin film transistor layer LTPS_TFT at the other side may be disposed on the light emitting element OLED at one side and the light emitting element OLED at the other side, respectively, with the opening 12 interposed therebetween. Here, the thin film transistor layers LTPS_TFT at one side and the other side may include a low temperature poly silicon (LTPS) type thin film transistor TFT formed by stacking one or more thin films. In this case, the LTPS type TFT may include a semiconductor layer, and both edges of the semiconductor layer may be doped with impurities.

In addition, an upper substrate GLS may be disposed on the thin film transistor layer LTPS_TFT at one side, the opening 12, and the thin film transistor layer LTPS_TFT at the other side.

The upper substrate GLS may be a glass substrate or a plastic substrate. For example, the plastic substrate may use polyimide (PI), but is not limited thereto. The upper substrate GLS may be, for example, cover glass (CG). The upper substrate GLS may be disposed to cover the front surface of the first display panel 10 to protect the first display panel 10 from an external impact.

Since the upper substrate GLS includes an active area AA in which images are displayed, the upper substrate GLS may be made of a transparent material for displaying the images. For example, the upper substrate GLS may be made of a transparent plastic, glass, or reinforced glass material.

Referring to FIG. 4, the second display panel 20 according to the embodiment of the present specification may have the light emitting element OLED disposed on a lower substrate C_BP and the thin film insulating layer TFE disposed on the light emitting element OLED.

The lower substrate C_BP may include a CMOS back plate BP. The lower substrate C_BP may be a silicon wafer substrate formed using a semiconductor process. An active layer is formed inside the wafer substrate, and gate lines, data lines, and transistors may be disposed on an upper surface of the wafer substrate.

A first electrode, an organic light emitting layer, and a second electrode are sequentially formed on the lower substrate C_BP to form the light emitting element OLED. The first electrode has a plurality of R (Red) sub-pixels, G (Green) sub-pixels, and B (Blue) sub-pixels arranged to be spaced at regular intervals from each other on the lower substrate C_BP.

The organic light emitting layer is formed throughout the entirety of an upper portion of the lower substrate C_BP to cover the lower substrate C_BP and the first electrode. The organic light emitting layer is commonly formed in all R, G, and B sub-pixels to emit light to the pixels.

The second electrode is formed on the organic light emitting layer. The second electrode is formed throughout the entirety of the sub-pixels to apply a signal to all sub-pixels simultaneously.

Referring to FIG. 5, the display panel 30 according to the embodiment of the present specification may be formed by coupling (bonding) the first display panel 10 with the second display panel 20.

In this case, the second display panel 20 may be coupled with the first display panel 10 so that the first active area 26 corresponds to the opening 12 of the first display panel 10.

In addition, the second display panel 20 may be coupled with the first display panel 10 so that the bezel area BZA corresponds to the second active area 14 of the first display panel 10.

In the display panel 30 according to the embodiment of the present specification, the light emitting element OLED may first be disposed on the lower substrate C_BP, and the thin film insulating layer TFE may be disposed on the light emitting element OLED. Here, the light emitting element OLED may include one or more first sub-pixels SP1 disposed in the first active area 26.

In addition, the thin film insulating layer TFE at one side and the thin film insulating layer TFE at the other side may be disposed on the thin film insulating layer TFE with the open portion 12 interposed therebetween. The light emitting element OLED at one side and the light emitting element OLED at the other side may be disposed on the thin film insulating layer TFE at the one side and the thin film insulating layer TFE at the other side, respectively, with the opening 12 interposed therebetween. Here, the light emitting elements OLED at one side and the other side may include one or more second sub-pixels SP2 disposed in the second active area 14 and include one or more third sub-pixels SP3 disposed in the third active area 16.

In addition, a thin film transistor layer LTPS_TFT at one side and a thin film transistor layer LTPS_TFT at the other side may be disposed on the light emitting element OLED at one side and the light emitting element OLED at the other side, respectively, with the opening 12 interposed therebetween.

In addition, an upper substrate GLS may be disposed on the thin film transistor layer LTPS_TFT at one side, the opening 12, and the thin film transistor layer LTPS_TFT at the other side.

The opening 12 of the first display panel 10 may include the upper substrate GLS.

Meanwhile, although not shown in FIGS. 3 to 5, the thin film insulating layer TFE may include an array layer as follows. For example, the array layer may have a buffer layer disposed on the substrate, and a patterned semiconductor layer on the buffer layer. The substrate may be a glass substrate or a plastic substrate, but is not limited thereto. The buffer layer may be made of an inorganic material such as silicon oxide (SiO₂) or silicon nitride (SiNₓ) and may be formed of a single layer or multiple layers. The semiconductor layer may be made of an oxide semiconductor material, and in this case, a shield pattern may be further formed under the semiconductor layer. The shield pattern prevents the degradation of the semiconductor layer due to light by blocking the light incident on the semiconductor layer and prevents the semiconductor layer from being deteriorated by light.

A gate insulating film made of an insulating material may be disposed on the entire surface of the substrate of the semiconductor layer. The gate insulating film may be made of an inorganic insulating material such as silicon oxide (SiO₂) or silicon nitride (SiNₓ).

In this case, when the semiconductor layer is made of an oxide semiconductor material, the gate insulating film may be made of silicon oxide (SiO₂). In contrast, when the semiconductor layer is made of polycrystalline silicon, the gate insulating film may be made of silicon oxide (SiO₂) or silicon nitride (SiNₓ).

A gate electrode made of a conductive material such as metal may be disposed on the gate insulating layer corresponding to the center of the semiconductor layer. In addition, a gate line may be disposed on the gate insulating film.

An interlayer insulating film made of an insulating material may be disposed on the entire surface of the substrate of the gate electrode. The interlayer insulating film may be made of an inorganic insulating material such as silicon oxide (SiO₂) or silicon nitride (SiNₓ), or may be made of an organic insulating material such as photo acryl or benzocyclobutene.

The interlayer insulating film has first and second contact holes exposing upper surfaces of both sides of the semiconductor layer. Source and drain electrodes made of a conductive material such as a metal may be disposed on the interlayer insulating film.

The source and drain electrodes are located to be spaced apart from the gate electrode and are in contact with both sides of the semiconductor layer through the first and second contact holes, respectively.

The semiconductor layer, the gate electrode, and the source and drain electrodes form a thin film transistor TFT. Here, the thin film transistor TFT may have a coplanar structure in which the gate electrode, and the source and drain electrodes are located at one side of the semiconductor layer, that is, on the semiconductor layer. In contrast, the thin film transistor TFT may have an inverted staggered structure in which the gate electrode is located under the semiconductor layer and the source and drain electrodes are located above the semiconductor layer. In this case, the semiconductor layer may be made of an oxide semiconductor material or amorphous silicon.

A protective film made of an insulating material may be disposed on the entire surface of the substrate of the source and drain electrodes. The protective film may be made of an organic insulating material such as photo acrylic or benzocyclobutene. The protective film has a flat upper surface.

An insulating film made of an inorganic insulating material such as silicon oxide (SiO₂) or silicon nitride (SiNₓ) may be further formed under the protective film, that is, between the thin film transistor TFT and the protective film.

The protective film has a drain contact hole exposing the drain electrode. Here, the drain contact hole may be formed to be spaced apart from the second contact hole. Alternatively, the drain contact hole may be formed directly above the second contact hole.

A first electrode made of a conductive material having a relatively high work function may be formed on the protective film. The first electrode is formed in each sub-pixel and is in contact with the drain electrode through the drain contact hole. For example, the first electrode may be made of a transparent conductive material such as indium tin oxide (ITO) or indium zinc oxide (IZO), but is not limited thereto.

The second display panel 20 according to the embodiment of the present disclosure may be a top emission type in which light of the light emitting element OLED is output in a direction opposite to the substrate, and thus, the first electrode may further include a reflective electrode or reflective layer made of a metal material having a high reflectance under the transparent conductive material. For example, the reflective electrode or the reflective layer may be made of an aluminum-palladium-copper (APC) alloy, silver (Ag), or aluminum (Al). In this case, the first electrode may have a triple-layer structure of ITO/APC/ITO, ITO/Ag/ITO, or ITO/AI/ITO, but is not limited thereto.

A bank made of insulating material is disposed on the first electrode. The bank overlaps an edge of the first electrode, covers the edge of the first electrode, and exposes a central portion of the first electrode. The bank may have at least a hydrophobic upper surface, and side surfaces of the bank may be hydrophobic or hydrophilic. The bank may be made of a hydrophobic organic insulating material. Alternatively, the bank may be made of a hydrophilic organic insulating material and treated to be hydrophobic.

The light emitting layer may be disposed on the first electrode exposed through the bank. The light emitting layer may include a first charge auxiliary layer, a light emitting material layer, and a second charge auxiliary layer that are sequentially located from an upper portion of the first electrode. The light emitting material layer may be made of any one of red, green, and blue light emitting materials, but is not limited thereto. The light emitting material may be an organic light emitting material such as a phosphorescent compound or a fluorescent compound. However, the present disclosure is not limited thereto, and an inorganic light emitting material such as quantum dots may be used.

The first charge auxiliary layer may be a hole auxiliary layer, and the hole auxiliary layer may be at least one of a hole injection layer HIL and a hole transport layer HTL. In addition, the second charge auxiliary layer may be an electron auxiliary layer, and the electron auxiliary layer may be at least one of an electron injection layer EIL and an electron transport layer ETL.

The light emitting layer may be formed through an evaporation process. In this case, a fine metal mask is used to pattern the light emitting layer for each sub-pixel. Alternatively, the light emitting layer may be formed through a solution process, and in this case, the height of the light emitting layer near the bank may increase as it approaches the bank.

The second electrode made of a conductive material having a relatively low work function may be disposed on substantially the entire surface of the substrate of the light emitting layer. Here, the second electrode may be made of aluminum, magnesium, silver, or an alloy thereof. In this case, the second electrode has a relatively small thickness to transmit light from the light emitting layer. In contrast, the second electrode may be made of a transparent conductive material such as indium gallium oxide (IGO), but is not limited thereto.

The first electrode, the light emitting layer, and the second electrode form the light emitting element OLED. Here, the first electrode may serve as an anode electrode, and the second electrode may serve as a cathode electrode.

As described earlier, the second display panel 20 according to the embodiment of the present specification may be a top emission type in which light from the light emitting layer of the light emitting element OLED is output in a direction opposite to the substrate, that is, to the outside through the second electrode, and since the top emission type may have a wider emission area than the bottom emission type having the same area, it is possible to increase luminance and reduce consumed power.

An encapsulation layer EnCap may be disposed on substantially the entire surface of the substrate of the second electrode. The encapsulation layer EnCap prevents external moisture or oxygen from flowing into the light emitting element OLED.

The encapsulation layer EnCap may have a stacking structure of a first inorganic film, an organic film, and a second inorganic film. Here, the organic film may be a film for covering foreign substance generated during the manufacturing process. The organic film may be made of an organic material such as an acrylic resin, an epoxy resin, polyimide, polyethylene, or silicon oxycarbon (SiOC). In addition, the organic film may be formed through an inkjet method. The organic film may serve as a buffer for reducing stress between the layers due to bending of the display device 100 or serve to reinforce planarization performance.

Meanwhile, although not shown in the drawing, the second display panel 20 shown in FIG. 4 may have a back frame disposed at a back side thereof. The back frame may be disposed on a back surface of the second display panel 20 to accommodate the first display panel 10 and the second display panel 20 and may be in contact with the upper substrate GLS to support the upper substrate GLS.

The back frame may serve as a housing forming an outer rear surface of the display device 100 and may be made of a metal material such as aluminum (Al) or a polymer epoxy-based resin material. The embodiments of the present specification are not limited thereto.

In this case, the back frame may serve as a case forming the outermost portion of the display device 100, but is not limited thereto. For example, the back frame may serve as a middle frame portion that serves as a housing for protecting the rear surface of the second display panel 20.

Meanwhile, the upper substrate GLS may have a black matrix BM formed by applying black ink on a portion corresponding to a non-active area NA to prevent light leakage of the non-active area NA of the display panel 30.

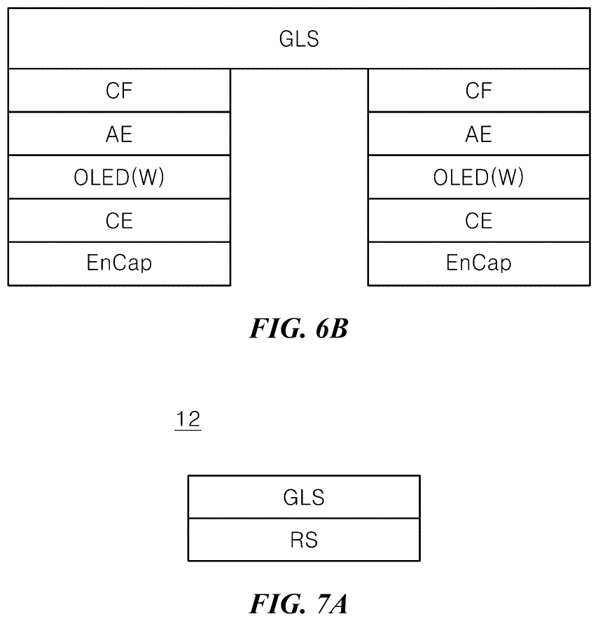

FIG. 6A is a cross-sectional view showing a cross-sectional structure of a first display panel 10′ according to the second embodiment of the present specification, and FIG. 6B is a cross-sectional view showing a cross-sectional structure of a first display panel 10 according to the third embodiment of the present specification.

Referring to FIG. 6A, the first display panel 10′ according to the second embodiment of the present specification may have a cathode electrode CE disposed on the encapsulation layer EnCap with an opening interposed therebetween, and the light emitting element OLED disposed on the cathode electrode CE with the opening interposed therebetween. Here, the light emitting element OLED may include one or more red sub-pixels (R), green sub-pixels (G), and blue sub-pixels (B).

In addition, an anode electrode AE may be disposed on the light emitting element OLED with the opening interposed therebetween, and the upper substrate GLS may be disposed on the anode electrode AE.

The encapsulation layer EnCap may have a single-layer structure or a multilayered structure. Although not shown in the drawing, the encapsulation layer EnCap may include, for example, a first encapsulation layer PAS1, a second encapsulation layer PCL, and a third encapsulation layer PAS2.

For example, the first encapsulation layer PAS1 and the third encapsulation layer PAS2 may be inorganic films, and the second encapsulation layer PCL may be an organic film. The second encapsulation layer PCL may be referred to as a particle cover layer PCL.

Among the first encapsulation layer PAS1, the second encapsulation layer PCL, and the third encapsulation layer PAS2, the second encapsulation layer PCL may be the thickest. Therefore, the second encapsulation layer PCL may serve as a planarization layer. The first encapsulation layer PAS1 may be referred to as a first inorganic encapsulation layer, the second encapsulation layer PCL may be referred to as an organic encapsulation layer, and the third encapsulation layer PAS2 may be referred to as a second inorganic encapsulation layer.

The first encapsulation layer PAS1 may be disposed on the cathode electrode CE and disposed closest to the light emitting element OLED. The first encapsulation layer PAS1 may be made of an inorganic insulating material capable of low-temperature deposition. For example, the first encapsulation layer PAS1 may be made of silicon nitride (SiNₓ), silicon oxide (SiOₓ), silicon oxynitride (SiON), or aluminum oxide (Al₂O₃). Since the first encapsulation layer PAS1 is deposited under a low-temperature atmosphere, during the evaporation process, the first encapsulation layer PAS1 can prevent damage to the light emitting layer EL containing an organic material vulnerable to a high-temperature atmosphere.

The second encapsulation layer PCL may be formed to have a smaller area than the first encapsulation layer PAS1. In this case, the second encapsulation layer PCL may be formed to expose both ends of the first encapsulation layer PAS1. The second encapsulation layer PCL may serve as a buffer for reducing stress between the layers due to bending of the display device 10 and serve to reinforce planarization performance. For example, the second encapsulation layer PCL may be made of an acrylic resin, an epoxy resin, polyimide, polyethylene, or silicon oxycarbon (SiOC) and may be made of an organic insulating material. For example, the second encapsulation layer PCL may be formed using an inkjet method.

The third encapsulation layer PAS2 may be formed on the substrate which the second encapsulation layer PCL is formed, to cover an upper surface and side surfaces of each of the second encapsulation layer PCL and the first encapsulation layer PAS1. The third encapsulation layer PAS2 can minimize or block external moisture or oxygen from permeating the first encapsulation layer PAS1 and the second encapsulation layer PCL. For example, the third encapsulation layer PAS2 may be made of an inorganic insulating material such as silicon nitride (SiNₓ), silicon oxide (SiOₓ), silicon oxynitride (SiON), or aluminum oxide (Al₂O₃).

Referring to FIG. 6B, the first display panel 10 according to the third embodiment of the present specification may have the cathode electrode CE disposed on the encapsulation layer EnCap with the opening interposed therebetween, and the light emitting element OLED disposed on the cathode electrode CE with the opening interposed therebetween. Here, the light emitting element OLED may include at least one white pixel W.

In addition, the anode electrode AE may be disposed on the light emitting element OLED with the opening interposed therebetween, a color filter CF may be disposed on the anode electrode AE, and the upper substrate GLS may be disposed on the color filter CF. Here, the color filter CF may include a red color filter R-CF, a green color filter G-CF, and a blue color filter B-CF.

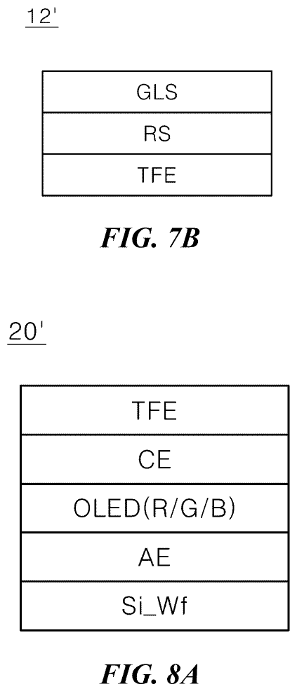

FIG. 7A is a cross-sectional view schematically showing a cross-sectional structure of an opening of the first display panel according to the embodiment of the present specification, and FIG. 7B is a cross-sectional view schematically showing a cross-sectional structure of an opening of a first display panel according to another embodiment of the present specification.

Referring to FIG. 7A, the opening 12 of the first display panel 10 according to the embodiment of the present specification may have, for example, the upper substrate GLS disposed on a resin film RS.

The resin film RS may be made of, for example, an organic material such as an acrylic resin, an epoxy resin, polyimide, polyethylene, or silicon oxycarbon (SiOC). In addition, the resin film may be formed through the inkjet method.

Referring to FIG. 7B, an opening 12′ of a first display panel 10 according to another embodiment of the present specification may have, for example, the resin film RS disposed on the thin film transistor TFE, and the upper substrate GLS disposed on the resin film RS.

Here, the thin film insulating layer TFE may have the same structure as the structure described above in FIGS. 3 to 5.

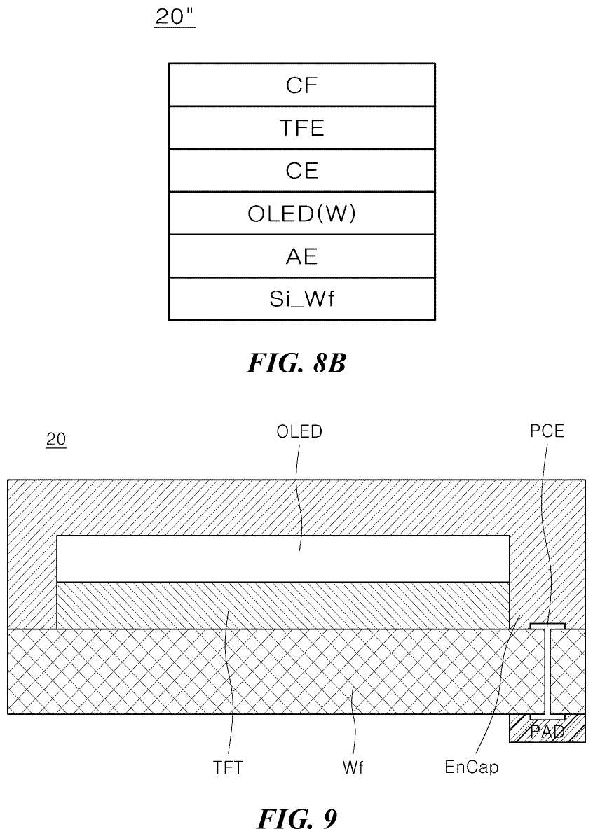

FIG. 8A is a cross-sectional view showing a cross-sectional structure of a second display panel 20′ according to the second embodiment of the present specification, and FIG. 8B is a cross-sectional view showing a cross-sectional structure of a second display panel 20″ according to the third embodiment of the present specification.

Referring to FIG. 8A, the second display panel 20′ according to the second embodiment of the present specification may have an anode electrode AE disposed on a CMOS-based wafer substrate Si_Wf containing silicon (Si).

In addition, a light emitting element OLED may be disposed on the anode electrode AE. Here, the light emitting element OLED may include one or more red sub-pixels (R), green sub-pixels (G), and blue sub-pixels (B).

In addition, a cathode electrode CE may be disposed on the light emitting element OLED, and a thin film insulating layer TFE may be disposed on the cathode electrode CE.

Here, the thin film insulating layer TFE may have the same structure as the structure described above in FIGS. 3 to 5.

Referring to FIG. 8B, a second display panel 20″ according to the third embodiment of the present specification may have an anode electrode AE disposed on a CMOS-based wafer substrate Si_Wf containing silicon (Si).

In addition, a light emitting element OLED may be disposed on the anode electrode AE. Here, the light emitting element OLED may include at least one white pixel W.

In addition, a cathode electrode CE may be disposed on the light emitting element OLED, and a thin film insulating layer TFE may be disposed on the cathode electrode CE. Here, the thin film insulating layer TFE may have the same structure as the structure described above in FIGS. 3 to 5.

In addition, a color filter CF may be disposed on the thin film insulating layer TFE. Here, the color filter CF may include a red color filter R-CF, a green color filter G-CF, and a blue color filter B-CF.

FIG. 9 is a view showing an example in which a pad portion is connected when a TFT is manufactured on the second display panel according to the embodiment of the present specification.

Referring to FIG. 9, a second display panel 20 according to the embodiment of the present specification may have a thin film transistor TFE disposed on a wafer substrate Wf.

In the second display panel 20, a light emitting element OLED may be disposed on a thin film transistor TFT, and an encapsulation layer EnCap may be disposed on the light emitting element OLED. The encapsulation layer EnCap seals the light emitting element OLED to cover the light emitting element OLED disposed on the thin film transistor TFT from the wafer substrate Wf.

The second display panel 20 may have a pad portion PAD disposed under the wafer substrate Wf.

In this case, the pad portion PAD may be in contact with one side of the connection electrode PCE passing through the wafer substrate Wf, and the other side of the connection electrode PCE may be disposed on the wafer substrate Wf.

Although not shown in the drawing, a driving integrated circuit D-IC may be disposed on the other surface of the pad portion PAD. The driving integrated circuit D-IC may be mounted on the second display panel 20 by a chip bonding process or a surface mounting process. Based on the bent state, the driving integrated circuit D-IC may be disposed under the second display panel 20.

In this case, a flexible printed circuit board may be disposed between the pad portion PAD and the driving integrated circuit D-IC, and the driving integrated circuit D-IC may be located on a back surface of the flexible printed circuit board.

The driving integrated circuit D-IC generates a data signal and a gate control signal based on image data and timing synchronization signals supplied from an external host driving system. In addition, the driving integrated circuit D-IC may supply the data signal to a data line of each pixel through the pad portion and supply the gate control signal to a gate driver.

The driving integrated circuit D-IC may be mounted on a chip mounting area defined in the second display panel 20 and electrically connected to the pad portion PAD, and may be connected to each of the gate driver and a signal line of a pixel array unit that are disposed on the second display panel 20.

Since the driving integrated circuit D-IC generates considerable heat, it is necessary to effectively dissipate heat from the driving integrated circuit D-IC. The driving integrated circuit D-IC may be primarily heat-dissipated by a support plate. A circuit board may provide the image data and the timing synchronization signals that are supplied from the host driving system to the driving integrated circuit and provide voltages required to drive each of the pixel array unit, a gate driving circuit unit, and a driving integrated circuit.

Meanwhile, although not shown in FIG. 9, the wafer substrate Wf may include, for example, a first substrate SUB1, an interlayer insulating layer IPD, and a second substrate SUB2. The interlayer insulating film IPD may be located between the first substrate SUB1 and the second substrate SUB2. Since the substrate SUB is formed of the first substrate SUB1, the interlayer insulating film IPD, and the second substrate SUB2, it is possible to prevent moisture permeation. For example, the first substrate SUB1 and the second substrate SUB2 may be polyimide (PI) substrates. The first substrate SUB1 may be referred to as a primary PI substrate, and the second substrate SUB2 may be referred to as a secondary PI substrate.

On the wafer substrate Wf, various patterns ACT, SD1, and GATE, various insulating films MBUF, ABUF1, ABUF2, GI, ILD1, ILD2, and PAS0, and various metal patterns TM, GM, ML1, and ML2 for forming a transistor such as the driving transistor DRT may be disposed.

A TR layer may be disposed on the second substrate SUB2. In the TR layer, the multi-buffer layer MBUF may be disposed on the second substrate SUB2, and the first active buffer layer ABUF1 may be disposed on the multi-buffer layer MBUF.

The first metal layer ML1 and a second metal layer ML2 may be disposed on the first active buffer layer ABUF1. Here, the first metal layer ML1 and the second metal layer ML2 may be a light shield layer LS for shielding light.

The second active buffer layer ABUF2 may be disposed on the first metal layer ML1 and the second metal layer ML2. The active layer ACT of the driving transistor DRT may be disposed on the second active buffer layer ABUF2.

The gate insulating layer GI may be disposed to cover the active layer ACT.

The gate electrode GATE of the driving transistor DRT may be disposed on the gate insulating film GI. In this case, the gate material layer GM may be disposed on the gate insulating film GI together with the gate electrode GATE of the driving transistor DRT at a location different from a formation location of the driving transistor DRT.

The first interlayer insulating layer ILD1 may be disposed to cover the gate electrode GATE and the gate material layer GM. The metal pattern TM may be disposed on the first interlayer insulating layer ILD1. The metal pattern TM may be located at a location different from the formation location of the driving transistor DRT. The second interlayer insulating film ILD2 may be disposed to cover the metal pattern TM on the first interlayer insulating film ILD1.

Two first source-drain electrode patterns SD1 may be disposed on the second interlayer insulating layer ILD2. One of the two first source-drain electrode patterns SD1 is the source node of the driving transistor DRT, and the other is the drain node of the driving transistor DRT.

The two first source-drain electrode patterns SD1 may be electrically connected to one side and the other side of the active layer ACT through contact holes of the second interlayer insulating film ILD2, the first interlayer insulating film ILD1, and the gate insulating film GI.

The second interlayer insulating film ILD2 may include a 2-1 interlayer insulating film ILD2-1 and a 2-2 interlayer insulating film ILD2-2. The 2-1 interlayer insulating film ILD2-1 may be located to cover the metal pattern TM. The 2-2 interlayer insulating film ILD2-2 may be located on the 2-1 interlayer insulating film ILD2-1.

A portion of the active layer ACT overlapping the gate electrode GATE is a channel area. One of the two first source-drain electrode patterns SD1 may be connected to one side of the channel area in the active layer ACT, and the other of the two first source-drain electrode patterns SD1 may be connected to the other side of the channel area in the active layer ACT.

A passivation layer PAS0 may be disposed on the 2-2 interlayer insulating layer ILD2-2. The passivation layer PAS0 is disposed to cover the two first source-drain electrode patterns SD1.

A planarization layer PLN may be disposed on the passivation layer PAS0. The planarization layer PLN may include a first planarization layer PLN1 and a second planarization layer PLN2. The first planarization layer PLN1 may be disposed on the passivation layer PAS0.

A second source-drain electrode pattern SD2 may be disposed on the first planarization layer PLN1. The second source-drain electrode pattern SD2 may be connected to one (corresponding to the second node N2 of the driving transistor DRT in the sub-pixel SP of FIG. 2) of the two first source-drain electrode patterns SD1 through the contact hole of the first planarization layer PLN1.

The second planarization layer PLN2 may be disposed to cover the second source-drain electrode pattern SD2.

A light emitting element layer PXL may be disposed on the second planarization layer PLN2. Referring to the stacking structure of the light emitting element layer PXL, the light emitting element layer PXL may be disposed on the second planarization layer PLN2 of the anode electrode AE. The anode electrode AE may be electrically connected to the second source-drain electrode pattern SD2 through the contact hole of the second planarization layer PLN2.

The bank BANK may be disposed to cover a portion of the anode electrode AE. A portion of the bank BANK corresponding to an emission area EA of the sub-pixel SP may be opened.

A portion of the anode electrode AE may be exposed to an opening (opened portion) of the bank BANK. The light emitting layer EL may be located on side surfaces of the bank BANK and the opening (opened portion) of the bank BANK. All or a portion of the light emitting layer EL may be located between adjacent banks BANK.

In the opening of the bank BANK, the light emitting layer EL may be in contact with the anode electrode AE. The cathode electrode CE may be formed on the light emitting layer EL.

The light emitting element PX may be formed by the anode electrode AE, the light emitting layer EL, and the cathode electrode CE. The light emitting layer EL may include an organic film.

The encapsulation layer EnCap may be disposed on the cathode electrode CE. The encapsulation layer EnCap may have the structure described above with reference to FIGS. 6A and 6B.

Although not shown in FIG. 9, the touch layer TL may be disposed on the encapsulation layer EnCap. When the touch layer TL is a type in which the touch sensor TS is embedded in the second display panel 20, the touch sensor TS may be disposed on the encapsulation layer EnCap. A structure of the touch sensor will be described in detail as follows.

A touch buffer film T-BUF may be disposed on the encapsulation layer EnCap. The touch sensor TS and a touch interlayer insulating layer T-ILD may be disposed on the touch buffer layer T-BUF.

The touch sensor TS may include touch sensor metals TSM and a bridge metal BRG located at different layers.

The touch interlayer insulating layer T-ILD may be disposed between the touch sensor metals TSM and the bridge metal BRG.

For example, the touch sensor metals TSM may include the first touch sensor metal TSM, the second touch sensor metal TSM, and the third touch sensor metal TSM disposed adjacent to each other. The third touch sensor metal TSM may be disposed between the first touch sensor metal TSM and the second touch sensor metal TSM, and when the first touch sensor metal TSM and the second touch sensor metal TSM are electrically connected, the first touch sensor metal TSM and the second touch sensor metal TSM may be electrically connected through the bridge metal BRG at different layers. The bridge metal BRG may be insulated from the third touch sensor metal TSM by the touch interlayer insulating layer T-ILD.

When the touch sensor TS is formed on the second display panel 20, a chemical solution (such as a developer or an etchant) used in the process may be introduced or moisture may be introduced from the outside. By arranging the touch sensor TS on the touch buffer film T-BUF, it is possible to prevent a chemical solution, moisture, etc., from permeating the light emitting layer EL containing an organic material during the manufacturing process of the touch sensor TS. Therefore, the touch buffer film T-BUF can prevent damage to the light emitting layer EL vulnerable to a chemical solution or moisture.

The touch buffer film T-BUF is made of an organic insulating material that may be formed at low temperatures smaller than a predetermined temperature (e.g., 100° C.) and has a low dielectric constant of 1 to 3 to prevent damage to the light emitting layer EL containing an organic material vulnerable to high temperatures. For example, the touch buffer film T-BUF may be made of an acrylic-based, epoxy-based, or siloxan-based material. As the display device 1 is bent, the encapsulation layer EnCap may be damaged, and the touch sensor metal located on the touch buffer film T-BUF may be broken. Even when the display device 100 is bent, the touch buffer film T-BUF made of an organic insulating material and having planarization performance can prevent the damage to the encapsulation layer EnCap and/or the breakage of the metals TSM and BRG forming the touch sensor TS.

The protective layer (PAC) may be disposed on the touch sensor TS and the touch interlayer insulating layer T-ILD. The protective layer PAC may be disposed to cover the touch sensor TS. The protective layer PAC may be made of an organic material.

Meanwhile, the encapsulation layer EnCap according to the embodiment of the present specification may be formed on the second display panel 20 by a manufacturing device. The manufacturing device may include a resin application valve (Jet valve) and an application nozzle. Therefore, a process of forming the encapsulation layer EnCap may be performed in a state in which a chip on film (COF), a flexible printed circuit board (FPCB), a FPC top liner, etc., are disposed.

The encapsulation layer EnCap may be formed by applying a mixed solution of a resin component and aluminum (Al) nanoparticles through the application nozzle in a state in which the resin application valve is located at the end of the second display panel 20.

The encapsulation layer EnCap formed by the above-described process may include aluminum (Al) nanoparticles to reflect ultraviolet (UV) light when irradiated with ultraviolet light.

Here, the aluminum nanoparticles were found to have a higher ultraviolet reflectance than other metal nanoparticles. The aluminum nanoparticles were found to be 0.9 when the wavelength (λ) of ultraviolet light was 350 nm. Therefore, it can be seen that aluminum has a higher reflectance than other metals when irradiated with ultraviolet light having the same wavelength.

The mixed solution of the resin component and the aluminum nanoparticles is a composite material of a resin and a metal, and with respect to ultraviolet light having the wavelength (λ) of 350 nm, 90% of the amount of ultraviolet light radiated to the encapsulation layer 200 may be reflected by the reflectance of the aluminum nanoparticles.

When the mixed solution of the resin component and the aluminum nanoparticles was a composite material and applied on the second display panel 20 in the thickness of 60 nm, it was found that the values of the reflectance and the modulus were high when the aluminum nanoparticles are precipitated at 10 vol % in the mixed solution. When the aluminum nanoparticles are precipitated in the thickness of 6 nm or less, which is 10 vol % of the total thickness of 60 nm of the encapsulation layer EnCap, the ultraviolet reflectance is shown to be about 90%, and the modulus is shown to be about 1,625 MPa.

The display device 100 according to the embodiment of the present specification may include a display panel 30 and a driving circuit for driving the display panel 30 although not shown in the drawing.

The driving circuit is a circuit for driving the display panel 30 and may include a data driver, a gate driver, a controller, etc.

The display panel 30 may include the active area AA in which images are displayed and the non-active area NA in which the images are not displayed. The non-active area NA may be an area outside the active area AA and is also referred to as the bezel area BZA. All or a portion of the non-active area NA may be an area visible from the front surface of the display device 100 or may be an area bent and not visible from the front surface of the display device 100.

The display panel 30 may include a plurality of sub-pixels SP1, SP2, and SP3 disposed on the substrate. In addition, the display panel 30 may further include various types of signal lines to drive a plurality of sub-pixels SP.

The display device 100 according to the embodiments of the present specification may be a light emitting display device in which the display panel 30 emits light by itself. When the display device 100 according to the embodiments of the present specification is a self-luminous display device, each of the plurality of sub-pixels SP may include the light emitting element OLED.

For example, the display device 100 according to the embodiments of the present specification may be an organic light emitting diode display device in which the light emitting element is implemented as the organic light emitting diode (OLED). For another example, the display device 10 according to the embodiments of the present specification may be an inorganic light emitting display device in which the light emitting element is implemented as an inorganic material-based light emitting diode. For still another example, the display device 10 according to the embodiments of the present specification may be a quantum dot display device in which the light emitting element is implemented as quantum dots that are semiconductor crystals emitting light by themselves.

The structure of each sub-pixel SP may be changed depending on the type of display device 100. For example, when the display device 100 is a self-luminous display device in which the sub-pixels SP emit light by themselves, each sub-pixel SP may include a light emitting element that emits light by itself, one or more transistors, and one or more capacitors.

For example, various types of signal lines may include a plurality of data lines DL through which data signals (referred to as data voltages or image signals) are transmitted, a plurality of gate lines GL through which gate signals (referred to as scan signals) are transmitted, etc.

The plurality of data lines DL and the plurality of gate lines GL may intersect each other. Each of the plurality of data lines DL may be disposed to extend in a first direction. Each of the plurality of gate lines GL may be disposed to extend in a second direction.

Here, the first direction may be a column direction, and the second direction may be a row direction. The first direction may be the row direction, and the second direction may be the column direction.

The data driver is a circuit configured to drive the plurality of data lines DL and may output the data signals to the plurality of data lines DL. The data driver may supply the data voltages to the display panel 30.

The gate driver is a circuit configured to drive the plurality of gate lines GL and may output the gate signals to the plurality of gate lines GL. The gate driver may supply the gate signals to the display panel 30.

The controller may be a device configured to control the data driver and the gate driver. The controller may control the driving timing for the plurality of data lines DL and the driving timing for the plurality of gate lines GL.

The controller may supply a data driving control signal DCS to the data driver to control the data driver. The controller may supply a gate driving control signal GCS to the gate driver to control the gate driver.

The controller may receive input image data from the host system and supply image data Data to the data driver based on the input image data.

The data driver may supply data signals to the plurality of data lines DL according to the driving timing control of the controller.

The data driver may receive digital image data from the controller, convert the received image data Data into analog data signals, and output the analog data signals to the plurality of data lines DL.

The gate driver may supply the gate signals to the plurality of gate lines GL according to the timing control of the controller. The gate driver may receive a first gate voltage corresponding to a turn-on level voltage and a second gate voltage corresponding to a turn-off level voltage together with various gate driving control signals GCS, generate the gate signals, and supply the generated gate signals to the plurality of gate lines GL.

For example, the data driver may be connected to the display panel 30 using a tape automated bonding (TAB) method, connected to a bonding pad of the display panel 30 using a chip on glass (COG) or chip on panel (COP) method, or connected to the display panel 30 using a chip on film (COF) method.

The gate driver may be connected to the display panel 30 using the TAB method, connected to the bonding pad of the display panel 30 using the COG or COP method, or connected to the display panel 30 using the COF method. Alternatively, the gate driver may be formed in the non-active area NA of the display panel 30 in a gate in panel (GIP) type. The gate driver may be disposed on the substrate SUB or connected to the substrate SUB. In other words, when the gate driver is the GIP type, the gate driver may be disposed in the non-active area NA of the substrate SUB. The gate driver may be connected to the substrate when the gate driver is the COG type, the COF type, etc.

Meanwhile, a driving circuit of at least one of the data driver and the gate driver may be disposed in the active areas 26, 14, and 16 of the display panel 30. For example, the driving circuit of at least one of the data driver and the gate driver may be disposed not to overlap the sub-pixels SP1, SP2, and SP3 and may partially or entirely overlap the sub-pixels SP1, SP2, and SP3.

The data driver may be connected to one side (e.g., upper side or lower side) of the display panel 30. The date driver may be connected to both sides (e.g., upper and lower sides) of the display panel 30 or connected to two or more side surfaces among four side surfaces of the display panel 30 according to a driving method, a panel design method, etc.

The gate driver may be connected to one side (e.g., left side or right side) of the display panel 30. The gate driver may be connected to both sides (e.g., left and right sides) of the display panel 30 or connected to two or more side surfaces among four side surfaces of the display panel 30 according to a driving method, a panel design method, etc.

The controller may be implemented as a separate component from the data driver or implemented as an integrated circuit integrated with the data driver.

The controller may be a timing controller used in a typical display technology, a control device capable of further performing other control functions in addition to the timing controller, a control device different from the timing controller, or a circuit in the control device. The controller may be implemented as various circuits or electronic components, such as an integrated circuit (IC), a field programmable gate array (FPGA), an application specific integrated circuit (ASIC), and a processor.

The controller may be electrically connected to the data driver and the gate driver through a PCB, a flexible PCB (FPCB), etc.

The controller may transmit and receive signals to and from the data driver according to one or more predetermined interfaces. Here, for example, the interface may include a low voltage differential signaling (LVDS) interface, an embedded panel interface (EPI), a serial peripheral interface (SP1), etc.

To provide both an image display function and a touch sensing function, the display device 100 according to the embodiments of the present specification may include a touch sensor, and a touch sensing circuit for detecting whether touch has been caused by a touch object such as a finger or a pen or detecting a touch location by sensing the touch sensor.

The touch sensing circuit may include a touch driving circuit for driving and sensing the touch sensor and generating and outputting touch sensing data, a touch controller for sensing the occurrence of touch or detecting the touch location using the touch sensing data, etc.

The touch sensor may include a plurality of touch electrodes. The touch sensor may further include a plurality of touch lines for electrically connecting a plurality of touch electrodes with the touch driving circuit.

The touch sensor may be present outside the display panel 30 in the form of a touch panel or present inside the display panel 30.

When the touch sensor is present outside the display panel 30 in the form of a panel, the touch sensor is referred to as an external type touch sensor. When the touch sensor is an external type, the touch panel and the display panel 30 may be manufactured separately and coupled during the assembly process. The external type touch panel may include a touch panel substrate and a plurality of touch electrodes disposed on the touch panel substrate.

When the touch sensor is present inside the display panel 30, the touch sensor may be formed on the substrate SUB together with signal lines, electrodes, etc., related to display driving during the manufacturing process of the display panel 30.

The touch driving circuit may supply a touch driving signal to at least one of the plurality of touch electrodes and generate touch sensing data by sensing at least one of the plurality of touch electrodes.

The touch sensing circuit may perform touch sensing using a self-capacitance sensing method or a mutual-capacitance sensing method.

When the touch sensing circuit performs touch sensing using the self-capacitance sensing method, the touch sensing circuit may perform the touch sensing based on a capacitance between each touch electrode and the touch object (e.g., a finger or a pen).

According to the self-capacitance sensing method, each of the plurality of touch electrodes may serve as both a driving touch electrode and a sensing touch electrode. The touch driving circuit 160 may drive all or some of the plurality of touch electrodes and sense all or some of the plurality of touch electrodes.

When the touch sensing circuit performs the touch sensing using the mutual-capacitance sensing method, the touch sensing circuit may perform the touch sensing based on the capacitance between the touch electrodes.

According to the mutual-capacitance sensing method, the plurality of touch electrodes are divided into driving touch electrodes and sensing touch electrodes. The touch driving circuit may drive the driving touch electrodes and sense the sensing touch electrodes.

The touch driving circuit and touch controller included in the touch sensing circuit may be implemented as separate devices or implemented as a single device. In addition, the touch driving circuit and the data driver may be implemented as separate devices or implemented as a single device.

The display device 100 may further include a power supply circuit for supplying various types of power to the driving circuit and/or the touch sensing circuit, etc.

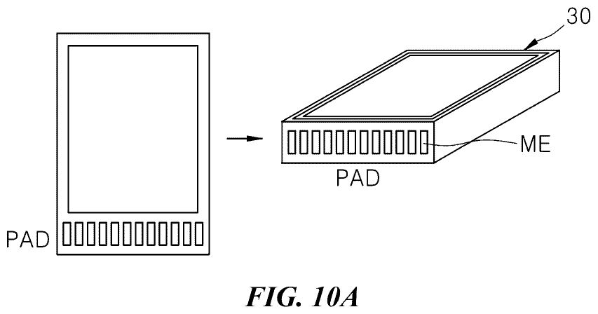

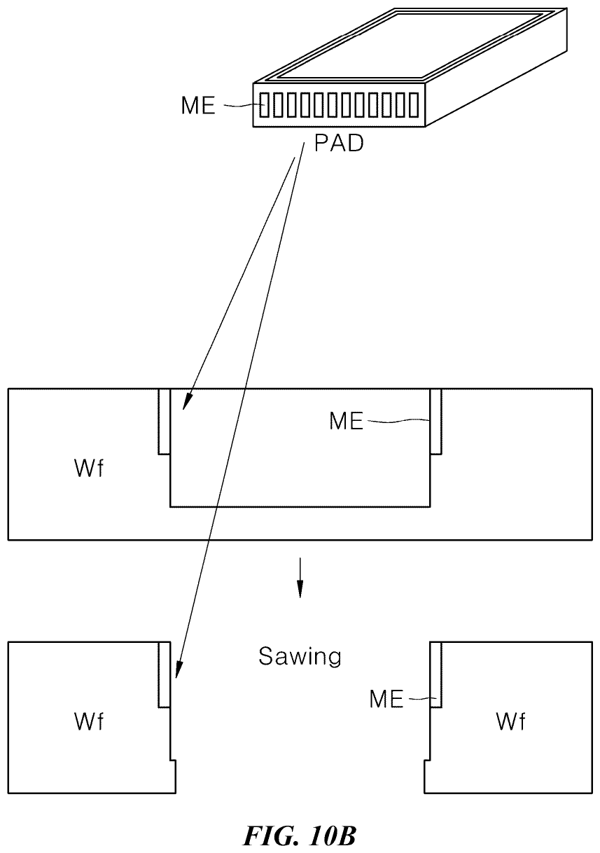

FIGS. 10A and 10B are views showing an example in which the pad portion is formed on the display panel according to the embodiment of the present specification.

Referring to FIGS. 10A and 10B, the display panel 30 according to the embodiment of the present specification may have the pad portion (PAD) formed on side surfaces thereof to implement an extreme bezel.

The display panel 30 according to the embodiment of the present specification may implement the narrow bezel by arranging the pad portion PAD previously located in the non-active area outside the lower side of the active area on side surfaces at the outermost side of the panel after eliminating the non-active area.

The arrangement structure of the pad portion PAD can allow the volume of production based on the production of the same screen inch panel to increase by 10% or more, thereby securing price competitiveness.

Referring to FIG. 10B, when the pad portion PAD is formed on side surface portions of the display panel 30, the pad portion PAD may be formed by arranging metal electrodes ME on the side surface portions at regular intervals.

In addition, it is possible to block the transfer of stress due to a step generated by etching a sawing line in advance on the wafer substrate Wf when the pad portion PAD is formed on the side surface portions of the display panel 30.

Therefore, it is possible to reduce damage to the sawing process to prevent the moisture permeation problem accordingly, thereby improving reliability.

According to the embodiments of the present specification, it is possible to implement a display device in which an ultra-high resolution can be implemented at half the prices of conventional display devices.

In addition, according to embodiments of the present specification, it is possible to implement a display device in which small-sized and ultra-high resolution pixels are disposed in a central area of a display panel and pixels greater and cheaper than the pixels disposed in the central area are disposed in a surrounding active area surrounding the central area.

According to the embodiments of the present specification, it is possible to implement the OLEDoG display device while implementing the OLEDOS display device.

Therefore, it is possible to provide the display device in which the ultra-high resolution can be implemented while providing the product at half or less the prices of conventional display devices.

Therefore, it is possible to secure price competitiveness in the display market in which VR display devices are provided.

In addition, according to the embodiment of the present specification, by implementing two types of the OLEDOS type and the OLEDOG type in one display device at the same time, the consumers do not need to separately purchase the AR display device and the VR display device, and thus it is possible to reduce the purchase cost.

In addition, according to the embodiment of the present specification, as the OLEDOS panel and the OLEDOG panel are applied, it is possible to prevent the decrease in the lifetime of the display device by repairing or replacing only the corresponding panel when each panel fails.

In addition, according to the embodiment of the present specification, by forming the pad portion PAD on the side surface portion of the display panel to remove the area of the pad portion PAD in the bezel area, it is possible to implement the extremely narrow bezel.

In addition, according to the embodiment of the present specification, by forming the pad portion PAD on the side surface portion of the display panel to increase the production volume based on the production of the same screen inch panel by 10% or more, it is possible to secure price competitiveness.

In addition, according to the embodiment of the present specification, by etching the sawing line on the wafer substrate in advance, it is possible to reduce damage in the sawing process and prevent the moisture permeation problem caused by the damage, thereby improving reliability.

In addition, according to the embodiments of the present specification, it is possible to prevent the occurrence of defects in the bezel area of the display device, thereby implementing the stable narrow bezel.

In addition, according to the embodiments of the present specification, it is possible to reduce the cost of the product by 50% or more while maintaining the characteristics of the conventional products perceived by consumers, thereby minimizing the decrease in the lifetime of the panel and improving the quality of the display device.

The effects of the present specification are not limited to the above-described effects, and other effects that are not mentioned will be able to be clearly understood by those skilled in the art from the following description.

Specific effects of the present specification together with the above-described effects are described together with a description of the following detailed matters for carrying out the embodiments of the specification.

Although the present specification has been described above with reference to the exemplary drawings, the present specification is not limited by the embodiments and drawings disclosed in the present specification, and it is apparent that various modifications can be made by those skilled in the art within the scope of the technical spirit of the present specification. In addition, even when the operational effects according to the configuration of the present specification have not been explicitly described in the description of the embodiments of the present specification, it goes without saying that the effects predictable by the corresponding configuration should also be recognized.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

### DESCRIPTION OF REFERENCE NUMERALS

| | |
|---|---|
| 100: display device | 10, 20, 30: display panels |
| 12: opening | 14: second active area |
| 16: third active area | 26: first active area |
| SP1, SP2, SP3: sub-pixels | Encap: encapsulation layer |
| GLS: upper substrate | OLED: light emitting element |
| C_BP: lower substrate | TFE: thin film insulating layer |
| LTPS_TFT: thin film transistor layer | AE: anode electrode |
| CE: cathode electrode | CF: color filter |
| RS: resin film | Si_Wf, Wf: wafer substrates |

1. A display device, comprising:
a first active area including one or more first sub-pixels;
a second active area including one or more second sub-pixels, the second active area surrounding the first active area; and
a third active area including one or more third sub-pixels, the third active area surrounding the second active area,
wherein a first active area has a first resolution that is different from one or more of a second resolution of the second active area or a third resolution of the third active area.

2. The display device of claim 1, further comprising: a first display panel including an opening corresponding to the first active area, the second active area surrounding the opening, and the third active area surrounding the second active area; and
a second display panel including the first active area, and a bezel area corresponding to the second active area and surrounding the first active area.

3. The display device of claim 2, wherein the first display panel is disposed over the second display panel.

4. The display device of claim 2, wherein the first display panel is structured to emit light in a bottom emission configuration, and
the second display panel is structured to emit light in a top emission configuration.

5. The display device of claim 2, wherein the first active area overlaps the opening, and the second active area overlaps the bezel area.

6. The display device of claim 1, wherein the first resolution is higher than the second resolution or the third resolution.

7. The display device of claim 1, wherein the second sub-pixel has a width of 1 mm to 2 mm, inclusive.

8. The display device of claim 1, wherein an area of the third sub-pixel is greater than an area of the first sub-pixel or an area of the second sub-pixel.

9. The display device of claim 2, wherein the second display panel has a greater area than an area of the opening of the first display panel.

10. The display device of claim 1, wherein a first sub-pixel, a second sub-pixel, and a third sub-pixel each emits light of one of red, green, or blue.

11. The display device of claim 10, wherein the first active area has first sub-pixels of red, green, or blue repeatedly disposed sequentially in a first direction, and
the second active area and the third active area have sub-pixels of red, green, or blue repeatedly disposed sequentially in a second direction that crosses the first direction.

12. The display device of claim 10, wherein in the first active area, one or more first sub-pixels adjacent to the second active area are disposed to have a same color as adjacent second sub-pixels in the second active area.

13. The display device of claim 10, wherein in the second active area, one or more second sub-pixels adjacent to the third active area have a same color as adjacent third sub-pixels in the third active area, and one or more second sub-pixels adjacent to the first active area have a same color as adjacent first sub-pixels in the first active area.

14. The display device of claim 2, wherein on the first display panel,
a thin film insulating layer at a first side and a thin film insulating layer at a second side are disposed with the opening interposed therebetween,
a light emitting element at the first side and a light emitting element at the second side are disposed on the thin film insulating layer at the first side and the thin film insulating layer at the second side, respectively, with the opening interposed therebetween,
a thin film transistor at the first side and a thin film transistor at the second side are disposed on the light emitting element at the first side and the light emitting element at the second side, respectively, with the opening interposed therebetween, and
an upper substrate is disposed on the thin film transistor at the first side, the opening, and the thin film transistor at the second side.

15. The display device of claim 2, wherein on the second display panel,
a light emitting element is disposed on a lower substrate, and
a thin film insulating layer is disposed on the light emitting element.

16. A display device, comprising:
a first display panel having a first substrate, a first display layer on the first substrate, a first insulation layer on the first display layer, and a first opening within the first insulation layer and within the first display layer leading to the first substrate; and
a second display panel on the first display panel and overlapping the first opening, the second display panel including a second insulation layer facing the first insulation layer, a second display layer on the second insulation layer, and a second substrate on the second display layer.

17. The display device of claim 16, wherein the second display panel fully covers the first opening.

18. The display device of claim 16, wherein the first display layer includes a bottom emission configuration, and the second display layer includes a top emission configuration.

19. The display device of claim 16, wherein the second display panel includes a bezel area that surrounds the second display layer, the bezel area partially overlapping the first display layer.

20. The display device of claim 16, wherein first display layer includes a first plurality of sub-pixels with a first resolution, the second display layer includes a second plurality of sub-pixels with a second resolution, and the second resolution is higher than the first resolution.
